(19) United States
(12) Patent Application Publication
(10) Pub. No.: US 2026/0168099 A1
(43) Pub. Date: Jun. 18, 2026

(54) NOZZLE INSTALLATION STRUCTURE OF LASER PROCESSING MACHINE

(71) Applicant: HK CO., LTD., Hwaseong-si, Gyeonggi-do (KR)

(72) Inventors: Su Bin CHOI, Hwaseong-si, Gyeonggi-do (KR); Man Sik PARK, Hwaseong-si, Gyeonggi-do (KR); Yang Jae SHIN, Hwaseong-si, Gyeonggi-do (KR)

(73) Assignee: HK CO., LTD., Hwaseong-si, Gyeonggi-do (KR)

(21) Appl. No.: 18/719,235

(22) PCT Filed: Jun. 23, 2023
(86) PCT No.: PCT/KR2023/008739

§ 371 Date: Jun. 12, 2024

(30) Foreign Application Priority Data
Jan. 4, 2023 (KR) 10-2023-0001009

(51) Int. Cl. C23C 16/455; B08B 5/02; B23K 26/14; C23C 16/44; C23C 16/458

(52) U.S. Cl. CPC C23C 16/45563; B08B 5/02; B23K 26/1476; C23C 16/4408; C23C 16/4412; C23C 16/45519; C23C 16/45561; C23C 16/45565; C23C 16/4585

(57) ABSTRACT

The present invention relates to a nozzle installation structure of a laser processing machine that can prevent contaminants such as spatters generated from the laser processing area from flowing into the head through the purge gas discharge gap under the processing head while effectively cooling the nozzle being processed. According to the nozzle installation structure of the laser processing machine of this invention, the purge gas discharged from the purge gas discharge gap at the bottom of the cover body is guided through the purge gas guider and discharged intensively close to the nozzle effectively cooling the nozzle. Meanwhile, most of the contaminants such as spatters generated from the laser processing portion and scattered at high speed are blocked by the spatter blocking plate minimizing the inflow of contaminants such as spatter into the head.

### FIELD OF THE INVENTION

The present disclosure relates to a nozzle installation structure of a laser processing machine, and more specifically, relates to a nozzle installation structure of a laser processing machine that can prevent contaminants such as spatters generated from the laser processing area from flowing into the head through a purge gas discharge gap under the processing head while effectively cooling the nozzle being processed.

### DESCRIPTION OF THE RELATED ART

A laser processing device is a device that processes a workpiece by concentrating a laser beam generated from a laser oscillator while passing through a processing head and irradiating it through a processing nozzle installed at the bottom of the processing head.

Referring to FIGS. 1 and 2 showing an example of laser processing head, a laser processing head 10 includes a housing 11 that maintains various internal optical devices, and a processing nozzle 20 is detachably connected to the lower part of the housing 11 via a nozzle adapter 30.

During the processing process, the nozzle 20 may be worn and contaminated and need to be replaced frequently, so the nozzle adapter 30 is detachably inserted and connected to the nozzle attachment 12 fixedly installed under the housing. The nozzle attachment 12 generally includes a sensor assembly (not shown) that detects the gap between the object to be processed and the processing nozzle 20, and a conical cover body 13 is installed outside the nozzle attachment to protect the sensor assembly.

The cover body 13 not only surrounds and protects the sensor assembly but also guides the purge gas (P.G) supplied through the supply flow path formed in the housing toward the processing nozzle.

### DOCUMENTS OF RELATED ART

### Patent Documents

(Patent Document 0001) Korean Patent Registration No. 10-2279676 (2021.07.14.)

### CONTENTS OF THE INVENTION

### Technical Problem to be Solved

However, according to the conventional nozzle installation structure as described above, the purge gas discharge portion formed by the gap G between the nozzle attachment 12 and the lower end of the cover body 13 is spaced apart from the nozzle, the role of the purge gas, that is, cooling the nozzle, was not performed effectively.

In addition, spatters (scattering molten metal) generated from the workpiece during processing are scattered and flow into the processing head through the gap, and the spatters introduced inside the processing head is stuck to the sensor assembly or retainer ring of the nozzle attachment 12 causing sensing instability. It was not easy to remove the hardened spatters.

On the other hand, in the case that another cover body is installed between the lower end of the cover body 13 and the nozzle to form the purge gas discharge part close to the nozzle in order to improve nozzle cooling effect, there was a problem that spatter generated instantaneously and at high speed and easily flows into the processing head through the extended purge gas passage.

The object of the present invention to solve the above mentioned problems is to provide a nozzle installation structure of a laser processing machine that can prevent contaminants such as spatters generated from the laser processing area from flowing into the head through the purge gas discharge gap under the processing head while effectively cooling the nozzle being processed.

### Technical Solution

To achieve the above mentioned object, a nozzle installation structure of the laser processing machine of this invention comprises a nozzle attachment installed under a processing head housing, a cover body installed outside the nozzle attachment and a processing nozzle combined to the nozzle attachment via a nozzle adapter, whereby purge gas supplied through a supply flow path formed in the housing is discharged through a purge gas discharge gap between the nozzle attachment and the lower end of the cover body. Wherein the nozzle installation structure further comprises: a spatter blocking plate having a plurality of purge gas discharge holes and combined to the outer periphery of the nozzle adapter; a purge gas guider disposed between the nozzle attachment and the spatter blocking plate and coupled to the outer periphery of the nozzle adapter; wherein the purge gas guider comprises an upper concave portion forming a ring-shaped space under the purge gas discharge gap, a lower concave portion forming a ring-shaped space above the upper part of the purge gas discharge hole of the spatter blocking plate and a plurality of purge gas through holes connecting the upper concave portion and the lower concave portion.

According to the nozzle installation structure of the present invention, it is possible to minimize the inflow of contaminants into the head while effectively cooling the nozzle. The purge gas discharged from the purge gas discharge gap at the bottom of the cover is guided through the purge gas guider and discharged intensively close to the nozzle effectively cooling the nozzle. Meanwhile, most of the contaminants such as spatters generated from the laser processing portion and scattered at high speed are blocked by the spatter blocking plate minimizing the inflow of contaminants such as spatter into the head.

In a preferred embodiment, it is desirable that each of the purge gas through holes is positioned so as not to overlap with each of the purge gas discharge holes when viewed from a vertical direction so that most of spatters that have passed through the purge gas discharge hole can not directly pass through the purge gas through hole and are captured in the ring-shaped space under the purge gas guider.

In addition, it is desirable that the plurality of purge gas through holes and the plurality of purge gas discharge holes are formed on a circumference with different diameters. Furthermore, it is preferable that the plurality of purge gas discharge holes going through the spatter blocking plate are formed on a circumference adjacent to the outer periphery of the nozzle adapter and the plurality of purge gas through holes going through the purge gas guider are formed on a circumference adjacent to the inner circumference of the lower concave portion of the purge gas guider.

According to the above mentioned feature of this invention, even if the spatters that occur instantaneously and penetrate the flow of purge gas at high speed passing through the purge gas discharge holes of the spatter blocking plate, it is difficult for the spatters to pass through the purge gas through holes which is positioned differently from the purge gas discharge holes. As a result, most of the spatters that passes through the purge gas discharge hole are captured in the ring-shaped space at the bottom of the purge gas guider, so the spatters can be more reliably prevented from flowing into the processing head and the spatters stuck on the bottom of the purge gas guider or the spatter blocking plate can be easily removed when replacing the nozzle.

The spatter blocking plate may be integrally formed on the outer periphery of the nozzle adapter, but may be formed separately from the nozzle adapter and inserted and combined to the outer periphery of the nozzle adapter.

The cover body is generally made of thin ceramic material. In order to prevent damage to the cover body due to close contact between the purge gas guider and the cover body, the inner wall of the upper concave portion of the purge gas guider is preferably arranged to have a predetermined gap from the lower part of the outer wall of the cover body 13, and an elastic sealing body is disposed in the gap to prevent leakage of the purge gas.

In addition, it is preferable that the inner wall of the purge gas guider is formed in the shape of a circular truncated cone with a wide top and a narrow bottom to provide a gap from the outer wall of the nozzle adapter.

Generally, a notch is formed on the top of the nozzle adapter, so that if the nozzle gets caught in an obstacle during the laser processing process, the notch is bent or cut to prevent damage to the nozzle attachment or sensor assembly coupled to the laser processing head. According to the above characteristic of this invention, it is possible to secure a bending or cutting space of the notch in the event of above mentioned nozzle contacting accidents.

### Effects of the Invention

According to the nozzle installation structure of the laser processing machine of this invention, the purge gas discharged from the purge gas discharge gap at the bottom of the cover body is guided through the purge gas guider and discharged intensively close to the nozzle effectively cooling the nozzle. Meanwhile, most of the contaminants such as spatters generated from the laser processing portion and scattered at high speed are blocked by the spatter blocking plate minimizing the inflow of contaminants such as spatter into the head.

### BRIEF DESCRIPTION OF THE DRAWINGS

FIG. 1 is an external view of a typical laser processing head.

FIG. 2 is a lower perspective view of the nozzle adapter of the laser processing head of FIG. 1 in an exploded state.

FIGS. 3A and 3B are perspective views of main components in an exploded state showing the nozzle installation structure according to an exemplary embodiment of the present invention.

FIG. 3C is a cross-sectional view of the main components in an assembled state showing the nozzle installation structure according to an exemplary embodiment of the present invention.

FIG. 4 is a cross-sectional view of the main components in an assembled state showing another exemplary embodiment of the nozzle installation structure according to the present invention.

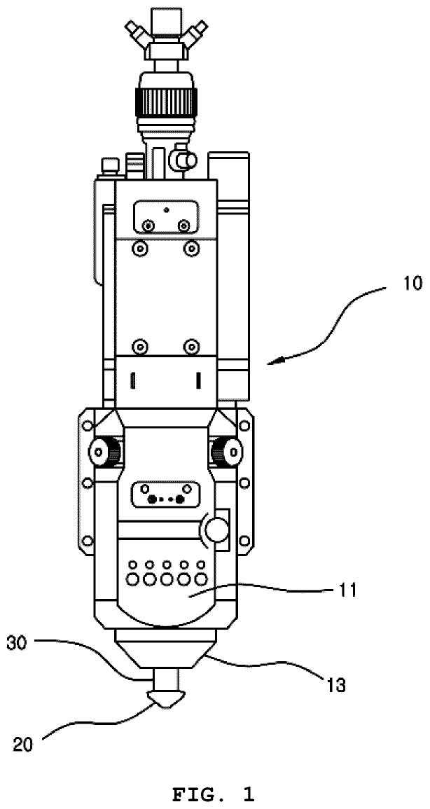

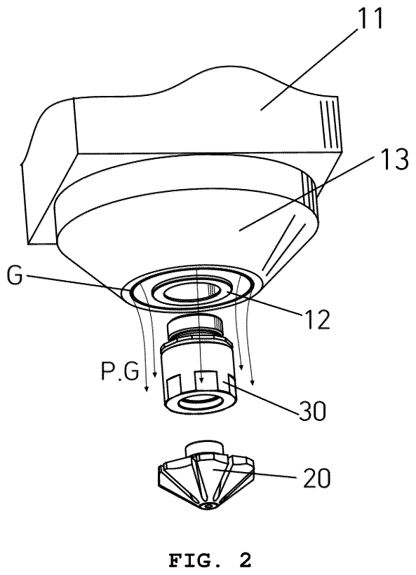

[EXPLANATION OF REFERENCE NUMERALS]

| | | | |
|---|---|---|---|
| 12: | nozzle attachment | 13: | cover body |
| 20: | processing nozzle | 30: | nozzle adapter |
| 40: | spatter blocking plate | 50: | purge gas guider |
| 41: | purge gas discharge hole | 51: | upper concave portion |
| 52: | lower concave portion | 53: | purge gas through hole |

### DETAILED DESCRIPTION OF THE INVENTION

Hereinafter, embodiments of the present invention will be described in detail with reference to the accompanying drawings, but identical or similar components will be assigned the same reference numbers and duplicate descriptions thereof will be omitted. In describing the embodiments disclosed in this specification, if it is determined that detailed descriptions of related known technologies may obscure the gist of the embodiments disclosed in this specification, the detailed descriptions will be omitted. In addition, the accompanying drawings are intended to make the embodiments disclosed herein easy to understand, and the technical ideas disclosed herein are not limited by the accompanying drawings, and it should be understood that all changes, equivalents or substitutes included in the spirit and technical scope of the present invention.

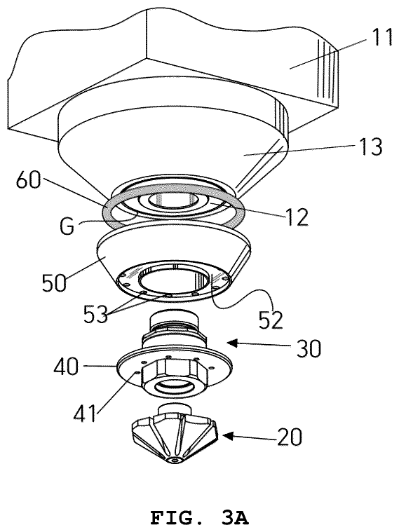

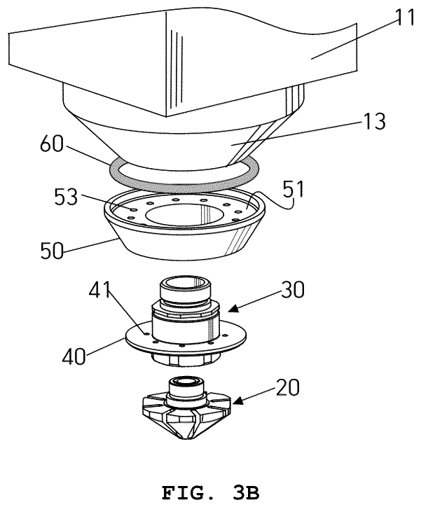

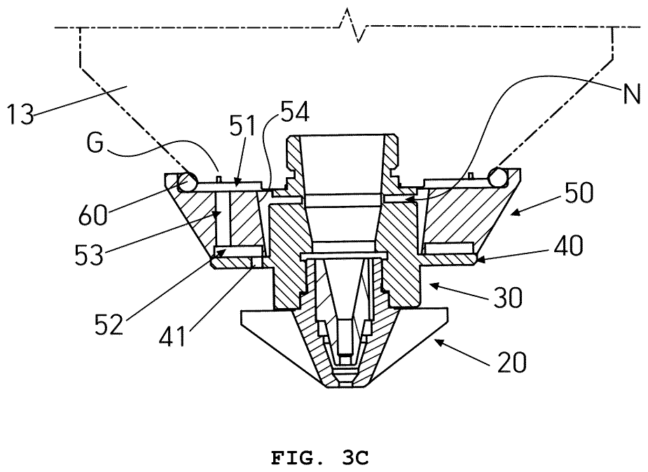

FIGS. 3A to 3C are diagrams showing the nozzle installation structure of a laser processing machine according to an embodiment of the present invention. The nozzle installation structure of the laser processing machine according to the present invention is similar to the general nozzle installation structure, which includes a nozzle attachment 12 installed under the processing head housing 11, a conical cover body 13 installed outside the nozzle attachment 12 to protect the nozzle attachment and sensor assembly (not shown). The purge gas supplied through the purge gas supply channel formed in the housing 11 is discharged through the gap (G) between the nozzle attachment 12 and the lower end of the cover body 13, and the processing nozzle 20 is coupled to the nozzle attachment 12 via the nozzle adapter 30. But, this invention is characterized in that a spatter blocking plate 40 having a plurality of purge gas discharge holes 41 is combined to the outer periphery of the nozzle adapter 30, and a separately formed purge gas guider 50 is disposed between the nozzle attachment 12 and the spatter blocking plate 40.

The spatter blocking plate 40 is formed to have a diameter larger than the outer diameter of the nozzle, preventing contaminants such as spatter generated by the laser processing portion and scattered at high speed from splashing upward, and supports the purge gas guider 50. A number of purge gas discharge holes 41 are formed in the spatter blocking plate (40) so that the purge gas supplied through the purge gas guider 50 can be discharged onto the top of the nozzle.

The purge gas guider 50 is a component that guides the purge gas discharged from the purge gas discharge gap (G) at the bottom of the cover body 13 to the purge gas discharge hole 41 of the spatter blocking plate 40, being formed in the shape of a circular truncated cone with a wide top and a narrow bottom, and combined to the outer periphery of the nozzle adapter 30. On the upper side of the purge gas guider 50, an upper concave portion 51 is formed to provide a ring-shaped space under the purge gas discharge gap (G), and a lower concave portion 52 is formed on the lower side of the purge gas guider 50 to provide a ring-shaped space above the upper part of the purge gas discharge hole of the spatter blocking plate. The upper concave portion 51 and the lower concave portion 52 is connected through a plurality of purge gas through holes 53.

The purge gas through hole 53 and the purge gas discharge hole 41 are formed on a circumference having different diameters. In this embodiment, the purge gas discharge holes 41 going through the spatter blocking plate 40 are formed on a circumference adjacent to the outer circumference of the nozzle adapter 30, and the purge gas through holes 53 going through the purge gas guider 50 are formed on a circumference adjacent to the inner circumference of the lower concave portion 52 of the purge gas guider 50.

Therefore, even if the spatters that occur instantaneously and penetrate the flow of purge gas at high speed passing through the purge gas discharge holes 41 of the spatter blocking plate 40, it is difficult for the spatters to pass through the purge gas through holes 53 which is positioned differently from the purge gas discharge holes 41 so that most of the spatters that passes through the purge gas discharge hole 41 are captured in the ring-shaped space at the bottom of the purge gas guider 50.

The cover body 13 is generally made of thin steel material or thin ceramic material. In order to prevent damage to the cover body 13 or the purge gas guider 50 due to close contact between the purge gas guider and the cover body when the processing nozzle 20 on the processing head collides with the workpiece, the inner wall of the upper concave portion 51 of the purge gas guider 50 is preferably arranged to have a predetermined gap from the lower part of the outer wall of the cover body 13, and an elastic sealing body 60 such as an o-ring is disposed in the gap to prevent leakage of the purge gas.

The elastic sealing body 60 serves to seal the purge gas, and at the same time serves to mitigate the impact on the purge gas guider 50 when the processing nozzle 20 collides with the workpiece during laser processing.

Generally, a notch N is formed on the top of the nozzle adapter 30, so that if the nozzle gets caught in an obstacle during the laser processing process, the notch N is bent or cut to prevent damage to the nozzle attachment or sensor assembly coupled to the laser processing head. In this embodiment, the inner wall 54 of the purge gas guider 50 is formed in the shape of a circular truncated cone with a wide top and a narrow bottom to provide a gap from the outer wall of the nozzle adapter 30 in order to secure a bending or cutting space of the notch N in the event of the nozzle contacting accidents.

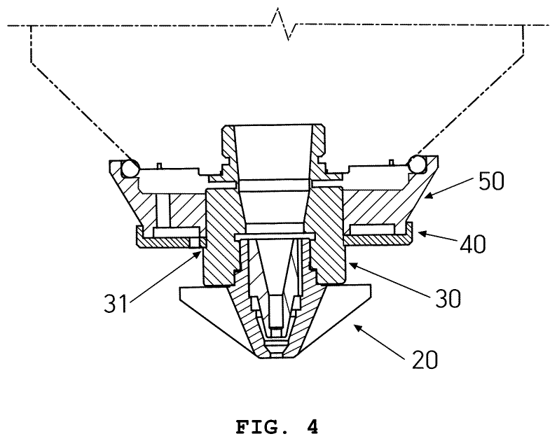

FIG. 4 is a diagram showing another embodiment of the present invention. Although the principle of guiding purge gas and blocking spatters is the same as the previous embodiment, but the spatter blocking plate 40 is formed separately from the nozzle adapter 30 and inserted and coupled to the outer periphery of the nozzle adapter 30, and the purge gas guider 50 is combined to the lower portion of the notch N of the nozzle adapter 30 to secure a bending or cutting space for the notch N.

The unexplained reference numeral 31 indicates a step portion formed on the outer periphery of the nozzle adapter 30 to support the spatter blocking plate 40.

According to the nozzle installation structure of the laser processing machine according to the present invention configured as described above, the purge gas discharged from the purge gas discharge gap (G) at the bottom of the cover body 13 is guided through the purge gas guider 50 and discharged intensively close to the processing nozzle 20 effectively cooling the nozzle. Meanwhile, most of the contaminants such as spatters generated from the laser processing portion and scattered at high speed are blocked by the spatter blocking plate minimizing the inflow of contaminants such as spatter into the head.

In addition, even if some of the spatters penetrate the flow of purge gas and flows in through the purge gas discharge hole 41 formed in the spatter blocking plate 40, since the flow direction of the spatter, that is, the upper part of the purge gas discharge hole 41 is blocked, most of the spatters are captured in the ring-shaped space under the purge gas guider 50, so that the spatters can be more reliably prevented from flowing into the processing head and the spatters stuck on the bottom of the purge gas guider 50 or the spatter blocking plate 40 can be easily removed when replacing the nozzle 20.

Although the present invention has been described using a specific type of nozzle as an example for convenience of explanation, it is obvious that the present invention may be applied to other types of nozzles in the same principle.

The present disclosure is not limited to the specific exemplary embodiment described above, and various modifications can be made by any person skilled in the art to which the present disclosure pertains without departing from the subject matter of the present disclosure as claimed, and the modifications are within the scope defined by the claims.

1. A nozzle installation structure of the laser processing machine comprising a nozzle attachment (12) installed under a processing head housing (11), a cover body (13) installed outside the nozzle attachment (30) and a processing nozzle (20) combined to the nozzle attachment (12) via a nozzle adapter (30), whereby purge gas supplied through a supply flow path formed in the housing (11) is discharged through a purge gas discharge gap (G) between the nozzle attachment (12) and the lower end of the cover body (13),
the nozzle installation structure further comprising:
a spatter blocking plate (40) having a plurality of purge gas discharge holes (41) and combined to the outer periphery of the nozzle adapter (30);
a purge gas guider (50) disposed between the nozzle attachment (12) and the spatter blocking plate (40) and combined to the outer periphery of the nozzle adapter (30);
wherein the purge gas guider (50) comprises an upper concave portion (51) forming a ring-shaped space under the purge gas discharge gap (G), a lower concave portion (52) forming a ring-shaped space above the upper part of the purge gas discharge hole (41) of the spatter blocking plate (40) and a plurality of purge gas through holes (53) connecting the upper concave portion (51) and the lower concave portion (52).

2. The nozzle installation structure of according to claim 1,
wherein each of the purge gas through holes (53) is positioned so as not to overlap with each of the purge gas discharge holes (41) when viewed from a vertical direction so that the spatters that have passed through the purge gas discharge holes (41) can not directly pass through the purge gas through holes (53) and are captured in the ring-shaped space under the purge gas guider (50).

3. The nozzle installation structure of according to claim 2,
wherein the plurality of purge gas discharge holes (41) going through the spatter blocking plate (40) are formed on a circumference adjacent to the outer periphery of the nozzle adapter (30) and the plurality of purge gas through holes (53) going through the purge gas guider (50) are formed on a circumference adjacent to the inner circumference of the lower concave portion (52) of the purge gas guider (50).

4. The nozzle installation structure of according to claim 1,
wherein the spatter blocking plate (40) is integrally formed on the outer periphery of the nozzle adapter (30).

5. The nozzle installation structure of according to claim 1,
wherein the spatter blocking plate (40) is formed separately from the nozzle adapter (30) and inserted and combined to the outer periphery of the nozzle adapter (30).

6. The nozzle installation structure of according to claim 1,
wherein the inner wall of the upper concave portion (51) of the purge gas guider (50) is disposed to have a gap of predetermined distance from a lower part of the outer wall of the cover body (13), and an elastic sealing body (60) is disposed in the gap.

7. The nozzle installation structure of according to claim 1,
wherein the inner wall of the purge gas guider (50) is formed in the shape of a circular truncated cone with a wide top and a narrow bottom to provide a gap from the outer wall of the nozzle adapter (30).
